(19) United States
(12) Patent Application Publication
(10) Pub. No.: US 2020/0410197 A1
(43) Pub. Date: Dec. 31, 2020

(54) ULTRASONIC FINGERPRINT IDENTIFICATION ASSEMBLY, ULTRASONIC FINGERPRINT IDENTIFICATION DEVICE, AND DISPLAY APPARATUS

(71) Applicant: BOE TECHNOLOGY GROUP CO., LTD., Beijing (CN)

(72) Inventors: Lijun ZHAO, Beijing (CN); Haisheng WANG, Beijing (CN); Yingming LIU, Beijing (CN); Yanling HAN, Beijing (CN); Yuzhen GUO, Beijing (CN)

(21) Appl. No.: 16/911,378

(22) Filed: Jun. 24, 2020

(30) Foreign Application Priority Data
Jun. 27, 2019 (CN) 201910566994.6

(51) Int. Cl. G06K 9/00; H01L 41/047

(52) U.S. Cl. CPC G06K 9/0002; H01L 41/0478; H01L 41/0474

(57) ABSTRACT

Embodiments of the present disclosure propose an ultrasonic fingerprint identification assembly, an ultrasonic fingerprint identification device, and a display apparatus. In one embodiment, the ultrasonic fingerprint identification assembly includes: a substrate; a receiving electrode on a side of the substrate; a piezoelectric layer on a side of the receiving electrode away from the substrate; a transmitting electrode on a surface of the piezoelectric layer away from the substrate; and a metal electrode, electrically connected to the transmitting electrode. An orthographic projection of the piezoelectric layer on the substrate falls within a combination of orthographic projections of the receiving electrode and the metal electrode on the substrate.

### CROSS-REFERENCE TO RELATED APPLICATION

This application claims priority of Chinese Patent Application No. 201910566994.6 filed on Jun. 27, 2019 in China National Intellectual Property Administration, the disclosure of which is incorporated herein by reference in entirety.

### TECHNICAL FIELD

Embodiments of the present disclosure relate to the field of fingerprint identification technology, and in particular, to an ultrasonic fingerprint identification assembly, an ultrasonic fingerprint identification device, and a display apparatus.

### BACKGROUND

Currently, the structural design of the large-sized ultrasonic fingerprint identification assembly needs to be improved.

### SUMMARY

In a first aspect of the present disclosure, there is provided an ultrasonic fingerprint identification assembly.

According to embodiments of the present disclosure, an ultrasonic fingerprint identification assembly includes: a substrate; a receiving electrode on a side of the substrate; a piezoelectric layer on a side of the receiving electrode away from the substrate; a transmitting electrode on a surface of the piezoelectric layer away from the substrate; and a metal electrode electrically connected to the transmitting electrode; wherein an orthographic projection of the piezoelectric layer on the substrate falls within a combination of orthographic projections of the receiving electrode and the metal electrode on the substrate.

According to embodiments of the present disclosure, a material for forming the metal electrode comprises at least one of copper, molybdenum, or titanium-aluminum-titanium, a material for forming the transmitting electrode comprises silver, and a material for forming the receiving electrode comprises indium tin oxide.

According to embodiments of the present disclosure, the metal electrode is disposed on a side of the receiving electrode away from the piezoelectric layer.

According to embodiments of the present disclosure, the metal electrode is electrically connected to the transmitting electrode through a via hole.

According to embodiments of the present disclosure, the ultrasonic fingerprint identification assembly further comprises: a thin film transistor between the receiving electrode and the substrate, a drain of the thin film transistor being electrically connected to the receiving electrode.

According to embodiments of the present disclosure, the ultrasonic fingerprint identification assembly further comprises: a buffer layer between the substrate and the thin film transistor, wherein the metal electrode is disposed between the substrate and the buffer layer, and the metal electrode is connected to the transmitting electrode through a via hole in the buffer layer.

According to embodiments of the present disclosure, the metal electrode has an opening, and an orthographic projection of an active layer of the thin film transistor on the substrate at least partially overlaps with an orthographic projection of the opening on the substrate.

According to embodiments of the present disclosure, the orthographic projection of the piezoelectric layer on the substrate falls within the orthographic projection of the metal electrode on the substrate.

According to embodiments of the present disclosure, an organic film layer of the thin film transistor comprises a first organic film layer and a second organic film layer stacked on each other, and the metal electrode patterned is disposed between the first organic film layer and the second organic film layer.

According to embodiments of the present disclosure, the ultrasonic fingerprint identification assembly further comprises: an insulating layer between the piezoelectric layer and the receiving electrode.

In a second aspect of the present disclosure, there is provided an ultrasonic fingerprint identification device.

According to embodiments of the present disclosure, the ultrasonic fingerprint identification device includes the abovementioned ultrasonic fingerprint identification assembly.

According to embodiments of the present disclosure, a material for forming the metal electrode comprises at least one of copper, molybdenum, or titanium-aluminum-titanium, a material for forming the transmitting electrode comprises silver, and a material for forming the receiving electrode comprises indium tin oxide.

According to embodiments of the present disclosure, the metal electrode is disposed on a side of the receiving electrode away from the piezoelectric layer.

According to embodiments of the present disclosure, the metal electrode is electrically connected to the transmitting electrode through a via hole.

According to embodiments of the present disclosure, the ultrasonic fingerprint identification assembly further comprises: a thin film transistor between the receiving electrode and the substrate, a drain of the thin film transistor being electrically connected to the receiving electrode.

According to embodiments of the present disclosure, the ultrasonic fingerprint identification assembly further comprises a buffer layer between the substrate and the thin film transistor, wherein the metal electrode is disposed between the substrate and the buffer layer, and the metal electrode is connected to the transmitting electrode through a via hole in the buffer layer.

According to embodiments of the present disclosure, the metal electrode has an opening, and an orthographic projection of an active layer of the thin film transistor on the substrate at least partially overlaps with an orthographic projection of the opening on the substrate.

According to embodiments of the present disclosure, the orthographic projection of the piezoelectric layer on the substrate falls within the orthographic projection of the metal electrode on the substrate.

According to embodiments of the present disclosure, an organic film layer of the thin film transistor comprises a first organic film layer and a second organic film layer stacked on each other, and the metal electrode patterned is disposed between the first organic film layer and the second organic film layer.

In a third aspect of the present disclosure, there is provided a display apparatus.

According to embodiments of the present disclosure, the display apparatus comprises: a display panel; and the abovementioned ultrasonic fingerprint identification, the ultrasonic fingerprint identification assembly being disposed on a non-light-emitting surface of the display panel.

Additional aspects and advantages of the present disclosure will be partially given in the following description, some of them will become apparent from the following description, or will be learned through the implementation of the present disclosure.

### BRIEF DESCRIPTION OF THE DRAWINGS

The above-mentioned aspects of the present disclosure will be explained by the description of the embodiments in conjunction with the following drawings, in which:

FIG. 1 is a schematic plan view showing a structure of an ultrasonic fingerprint identification assembly in the related art;

FIG. 2 is a schematic top view showing a structure of an ultrasonic fingerprint identification assembly according to an embodiment of the present disclosure;

FIG. 3 is a schematic partial cross-sectional view showing a structure of an ultrasonic fingerprint identification assembly according to an embodiment of the present disclosure;

FIG. 4 is a schematic partial cross-sectional view showing a structure of an ultrasonic fingerprint identification assembly according to another embodiment of the present disclosure; and

FIG. 5 is a schematic partial cross-sectional view showing a structure of an ultrasonic fingerprint identification assembly according to yet another embodiment of the present disclosure.

### DETAILED DESCRIPTION OF EMBODIMENTS

The embodiments of the present disclosure will be described in detail below. It should be understood by those skilled in the art that the following embodiments are intended to explain the present disclosure, but not to limit the present disclosure. Unless specifically stated, if specific techniques or conditions are not explicitly described in the following embodiments, then they may be practiced by those skilled in the art according to common techniques or conditions in the related art or according to product specifications.

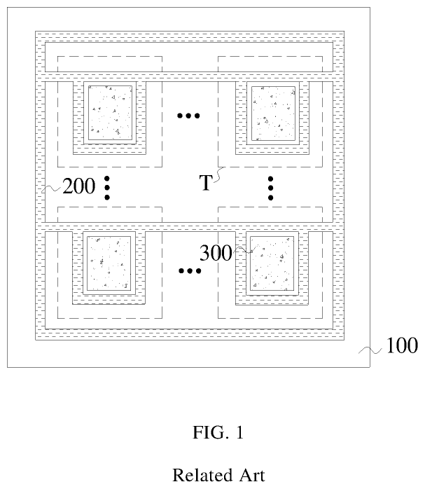

At present, ultrasonic fingerprint identification devices generally have a dimension comparative to that of a finger. Referring to FIG. 1, after the manufacture of the back plate of a receiving (Rx) electrode 200 is completed, a piezoelectric layer (Piezo) 300 of polyvinylidene fluoride (PVDF) material is formed by coating, then by connecting the ring-shaped receiving (Rx) electrode 200 to a charged polarization device, an electric field formed by the ring-shaped receiving electrode 200 can polarize the PVDF, and the polarized piezoelectric layer 300 has a piezoelectric effect. After polarization, the transmitting (Tx) electrode is finally manufactured on the PVDF. It should be noted that only the substrate 100, the receiving electrode 200, and the piezoelectric layer 300 are shown in FIG. 1 but other structures are not shown.

However, in a case where a large-sized ultrasonic fingerprint identification device is intended to be developed, if the structure of a finger-sized device is still used, that is, the polarization manner with a ring-shaped pattern is used, the fringe field strength will weaken as the distance increases, resulting in a poor effect of PVDF polarization, and thereby resulting in a low piezoelectric conversion efficiency. In addition, if the large-size transmitting electrode is still patterned on the basis of the display panel, then the voltage drive of the transmitting (Tx) electrode will have different voltage drops depending on the position, due to a larger square resistance of silver paste, thus the excitation of the transmitting (Tx) electrode driven onto the PVDF also has a different ultrasonic energy generated depending on the position. Thus, it will cause the energy reflected by the finger to be different due to the difference in driving excitation, which cannot accurately reflected the signal difference produced by the valleys of the finger.

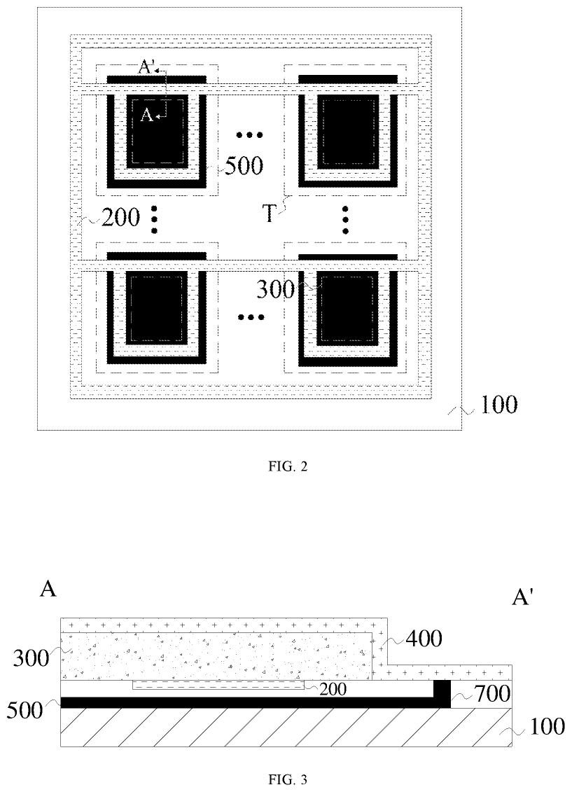

As mentioned above, the structural design of the large-sized ultrasonic fingerprint identification assembly needs to be improved at present. In one aspect of the present disclosure, there is proposed an ultrasonic fingerprint identification assembly. It should be noted that FIG. 2 only shows a substrate 100, a receiving electrode 200, a piezoelectric layer 300, and a metal layer 500 but does not show other structures, and FIGS. 3 to 5 are cross-sectional views along the section AA′ in FIG. 2.

According to the embodiments of the present disclosure, referring to FIGS. 2 and 3, the ultrasonic fingerprint identification assembly includes a substrate 100, a receiving electrode 200, a piezoelectric layer 300, a transmitting electrode 400 and a metal electrode 500. The receiving electrode 200 is disposed on a side of the substrate 100; the piezoelectric layer 300 is disposed on a side of the receiving electrode 200 away from the substrate 100; the transmitting electrode 400 is disposed on a surface of the piezoelectric layer 300 away from the substrate 100; and the metal electrode 500 is electrically connected to the transmitting electrode 400. Referring to FIG. 3, an orthographic projection of the piezoelectric layer 300 in each detection unit T on the substrate 100 falls within a combination of orthographic projections of the receiving electrode 200 and the metal electrode 500 on the substrate 100, that is, the orthographic projection of the piezoelectric layer 300 falls within the union of the orthographic projections of the receiving electrode 200 and the metal electrode 500.

The inventor of the present disclosure incorporates a patterned metal layer 500 into the structure of the ultrasonic fingerprint identification assembly of the present disclosure, the patterned metal layer may not only be connected to a ground electrode of a polarization device during polarization, work as a part of the polarizing electrode, thereby the polarization effect of the piezoelectric layer 300 is more uniform and the piezoelectric conversion efficiency is higher, and the metal layer 500 may also be electrically connected to the transmitting electrode 400, which can reduce the resistance of the transmitting electrode 400 (for example, formed by a silver (Ag) layer of 5-20 microns thickness)), so that the Tx driving at different positions on a large-sized device is more consistent, thereby improving the accuracy of detection on fingerprints or palm prints.

According to the embodiments of the present disclosure, the material for forming the metal electrode 500 may include at least one of copper (Cu), molybdenum (Mo), or titanium-aluminum-titanium (Ti/Ai/Ti), the material for forming the transmitting electrode 400 may include silver (Ag), and the material for forming the receiving electrode 200 may include indium tin oxide (ITO). In this way, the metal electrode 500 using the above conductive material can generate a polarization electric field, and the square resistance is small.

In some embodiments of the present disclosure, referring to FIG. 3, the metal electrode 500 may be disposed on the side of the receiving electrode 200 away from the piezoelectric layer 300. In this way, even if the metal electrode is electrically connected to the transmitting electrode 400, the metal electrode 500 will not affect the transmission of voltage signal from the receiving electrode 200 to the piezoelectric layer 300.

In some embodiments of the present disclosure, referring to FIG. 3, the metal electrode 500 may be electrically connected to the transmitting electrode 400 through a via hole 700. In this way, the transmitting electrode 400 and the metal electrode 500 respectively disposed on the upper and lower sides of the receiving electrode 200 may directly realize the electrical connection relationship therebetween through a through hole penetrating the dielectric layer.

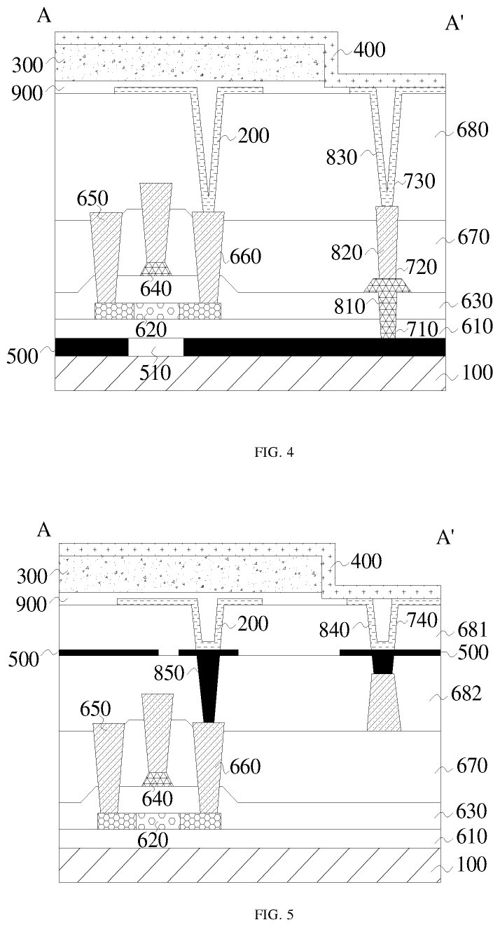

According to the embodiments of the present disclosure, referring to FIG. 4 or FIG. 5, the ultrasonic fingerprint identification assembly may further include a thin film transistor (TFT), which is disposed between the receiving electrode 200 and the substrate 100. Specifically, the thin film transistor may include an active layer 620, a gate insulating layer 630, a gate electrode 640, a source electrode 650, a drain electrode 660, an interlayer dielectric layer 670, and an organic film layer 680. The active layer 620 is disposed on a side of the substrate 100 facing the receiving electrode 200, the gate insulating layer 630 covers the surface of the active layer 620, the gate electrode 640 is disposed on a side of the gate insulating layer 630 away from the active layer 620, the interlayer dielectric layer 670 covers the gate electrode 640 and a part of the gate insulating layer 630, the source electrode 650 and the drain electrode 660 are in contact with the active layer 620 through via holes in the interlayer dielectric layer 670 and the gate insulating layer 630 respectively, and the organic film layer (680 in FIG. 4, and 681 and 682 in FIG. 5) covers the source electrode 650, the drain electrode 660, and a part of the interlayer dielectric layer 670. Moreover, the drain electrode 660 may be electrically connected to the receiving electrode 200 through a via hole in the organic film layer 680. In this way, the ultrasonic fingerprint identification assembly can have a more perfect structure and function.

In some embodiments of the present disclosure, referring to FIG. 4, a buffer layer 610 may be provided on a side of the substrate 100 close to the thin film transistor, that is, the buffer layer 610 is disposed between the substrate 100 and the thin film transistor, and the metal electrode 500 may be disposed between the substrate 100 and the buffer layer 610 (for example, formed of at least one of silicon nitride (SiNx), silicon oxide (SiOx), or an organic resin material). Moreover, the metal electrode 500 is connected to the transmitting electrode 400 through via holes in the buffer layer 610, the gate insulating layer 630, and the interlayer dielectric layer 670 and the organic film layer 680. In this way, the metal electrode 500 disposed on the surface of the substrate 100 can significantly reduce the resistance of the transmitting electrode 400, and it may also serve as a backplane Tx electrode, thereby avoiding the influence of the backplane Tx electrode on the TFT characteristics. In some specific examples, the orthographic projection of the piezoelectric layer 300 on the substrate 100 may fall within the orthographic projection of the metal electrode 500 on the substrate 100. In this way, the entire layer of metal electrode or the mesh-shaped metal electrode 500 may make the polarization effect of the piezoelectric layer 300 more uniform and make the piezoelectric conversion efficiency higher, and the mesh-shaped metal electrode 500 can also reduce the influence of capacitive coupling or the like on the metal wiring of the TFT.

In some specific examples, referring to FIG. 4, the metal electrode 500 may be electrically connected to the transmitting electrode 500 through a first electrode 810, a second electrode 820, and a third electrode 830. The first electrode 810 penetrates the buffer layer 610 and the gate insulating layer 630, and the first electrode 810 is arranged in the same layer as the gate electrode 640. The second electrode 820 penetrates the interlayer insulating layer 670, and the second electrode 820 is arranged in the same layer as the source electrode 650 and the drain electrode 660. The third electrode 830 penetrates the organic film layer 680, and the third electrode 830 is arranged in the same layer as the receiving electrode 200. Therefore, the first electrode 810 in direct contact with the metal layer 500 contacts with the second electrode 820 through a first via hole 710 in the buffer layer 610 and the gate insulating layer 630, the second electrode 820 contacts with the third electrode 830 through a second via hole 720 in the interlayer insulating layer 670, and the third electrode 830 contacts with the transmitting electrode 400 through a third via hole 730 in the organic film layer 680. It should be noted that the “arranged in a/the same layer” herein specifically means that the discussed components are made from the same raw materials and can be collectively formed by one patterning process.

In other specific examples, referring to FIG. 4, the metal electrode 500 may have an opening 510, and an orthographic projection of the active layer 620 of the thin film transistor on the substrate 100 at least partially overlaps with an orthographic projection of the opening 510 on the substrate 100. Specifically, the orthographic projection of the active layer 620 on the substrate 100 falls within the orthographic projection of the opening 510 on the substrate 100. In this way, the opening 510 in the metal electrode 500 can prevent other electrode signals from affecting the channel region of the active layer 620 of the TFT, thereby making the switching function of the TFT more accurate.

In other embodiments of the present disclosure, referring to FIG. 5, the organic film layer may include a first organic film layer 681 and a second organic film layer 682 that are stacked on each other, and the patterned metal electrode 500 may be disposed between the first organic film layer 681 and the second organic film layer 682. In this way, the capacitive coupling effect between the transmitting electrode 400 and the gate electrode 640, the source electrode 650, or the drain electrode 660 caused by the metal electrode 500 as the backplane Tx electrode can be significantly reduced. It should be noted that the “stacked on each other” herein specifically refers to that the discussed components are arranged in order in a direction perpendicular to the surface of the substrate 100 with a largest size.

In some specific examples, referring to FIG. 5, the metal electrode 500 may also be arranged in the same layer as a fifth electrode 850, and the fifth electrode 850 may penetrate the second organic film layer 682, and the fifth electrode 850 may electrically connect the receiving electrode 200 to the drain electrode 660. Moreover, the metal electrode 500 may be electrically connected to the transmitting electrode 400 through a fourth electrode 840, and the fourth electrode 840 may penetrate the first organic film layer 681, and the fourth electrode 840 may be arranged in the same layer as the receiving electrode 200. Therefore, the fourth electrode 840 in direct contact with the metal layer 500 contacts with the transmitting electrode 400 through a via hole 740 in the first organic film layer 681, and the fifth electrode 850 in direct contact with the receiving electrode 200 contacts with the drain electrode 660 through a fifth via hole in the second organic film layer 682. In this way, the electrical connection relationship between the metal electrode 500 and the transmitting electrode 400 can also be achieved.

In other specific examples, referring to FIG. 5, the metal electrode 500 may also have an opening, and an orthographic projection of the active layer 620 of the thin film transistor on the substrate 100 partially overlaps with an orthographic projection of the opening on the substrate 100. Specifically, the orthographic projection of the active layer 620 on the substrate 100 may fall within the orthographic projection of the opening on the substrate 100. In this way, the opening in the metal electrode 500 can prevent other electrode signals from affecting the channel region of the active layer 620 of the TFT, thereby making the switching function of the TFT more accurate.

According to the embodiments of the present disclosure, the specific material for forming the piezoelectric layer 300 may be selected accordingly by those skilled in the art according to the sensitivity requirements of the ultrasonic fingerprint identification assembly, for example ferroelectric polymer such as polyvinylidene fluoride (PVDF) or other ferroelectric materials, which will not be repeated here. In some embodiments of the present disclosure, the piezoelectric constant d33 of the piezoelectric material may be 25-33. It should be noted that the “piezoelectric constant” is one of the most commonly used important parameters to characterize the performance of the piezoelectric material, is a conversion coefficient of the piezoelectric body to convert mechanical energy into electrical energy or electrical energy into mechanical energy, reflects a coupling relationship between the elastic (mechanical) performance and the dielectric performance of the piezoelectric material. Thus, adopting the piezoelectric material with the above high piezoelectric constant may allow the piezoelectric layer 300 to be more sensitive. According to the embodiments of the present disclosure, as shown in FIG. 4 or FIG. 5, an insulating layer 900 may be further provided between the piezoelectric layer 300 and the receiving electrode 200. In this way, the interference of the characteristics of the piezoelectric layer 300 by the receiving electrode 200 may be avoided.

In summary, according to the embodiments of the present disclosure, an ultrasonic fingerprint identification assembly is proposed, the newly-incorporated patterned metal layer may not only work as a part of the polarizing electrode during polarization, thereby the polarization effect of the piezoelectric layer is more uniform and the piezoelectric conversion efficiency is higher, and the metal layer may also be electrically connected to the transmitting electrode, which can reduce the resistance of the transmitting electrode, so that the transmitting driving at different positions on a large-sized device is more consistent, thereby improving the accuracy of detection on fingerprints.

In another aspect of the present disclosure, there is proposed an ultrasonic fingerprint identification device. According to the embodiments of the present disclosure, the ultrasonic fingerprint identification device includes the ultrasonic fingerprint identification assembly described above.

According to the embodiments of the present disclosure, the specific type of the ultrasonic fingerprint identification device is not particularly limited, for example, the ultrasonic fingerprint identification device may be a fingerprint lock, a fingerprint identification module of an electronic device, etc. It may be accordingly determined by those skilled in the art according to the actual use environment and the functional requirement of the ultrasonic fingerprint identification device, which will not be repeated here. It should be noted that, in addition to the above-mentioned ultrasonic fingerprint identification assembly, the ultrasonic fingerprint identification device also includes necessary components and structures. Taking a fingerprint lock as an example, a case, a power supply, a circuit board or a control module, etc. is included, and those skilled in the art may accordingly design it or supplement the necessary components and structures according to the specific type of the ultrasonic fingerprint identification device, which will not be repeated here.

In summary, according to the embodiments of the present disclosure, it proposes an ultrasonic fingerprint identification device, the ultrasonic fingerprint identification assembly of which may detect the fingerprint more accurately, thereby making the ultrasonic fingerprint identification device more sensitive. It should be understood by those skilled in the art that the features and advantages described above for the ultrasonic fingerprint identification assembly are still applicable to the ultrasonic fingerprint identification device, and therefore they will not be repeated here.

In yet another aspect of the present disclosure, there is provided a display apparatus.

According to the embodiments of the present disclosure, the display apparatus includes a display panel and the above-mentioned ultrasonic fingerprint identification assembly, and the ultrasonic fingerprint identification assembly is disposed on a non-light-emitting surface of the display panel.

According to the embodiments of the present disclosure, the specific type of the display apparatus is not particularly limited, for example, the display apparatus may be a display screen, a TV, a mobile phone, a tablet computer, or a smart watch, etc. It may be accordingly determined by those skilled in the art according to the actual use requirement of the display apparatus, which will not be repeated here. It should be noted that, in addition to the display panel and the ultrasonic fingerprint identification assembly, the display apparatus also includes other necessary components and structures. Taking a display screen as an example, a case, a control circuit board, or a power cord, etc. is included, and those skilled in the art may accordingly supplement the necessary components and structures according to the function of the display apparatus, which will not be repeated here.

In summary, according to the embodiments of the present disclosure, it proposes a display apparatus, the ultrasonic fingerprint identification assembly of which may detect the fingerprint more accurately, thereby making the fingerprint identification function of the display apparatus more sensitive, and thus enabling the display apparatus to have a full-screen fingerprint identification function while realizing the display function. It should be understood by those skilled in the art that the features and advantages described above for the ultrasonic fingerprint identification assembly are still applicable to the display apparatus, and therefore they will not be repeated here.

In the description of the present disclosure, it should be understood that the terms “first” and “second” are only used for descriptive purposes, and should not be understood as indicating or implying relative importance or implicitly indicating the number of the indicated technical features. Thus, the features defined with “first” and “second” may include at least one of the features either explicitly or implicitly. In the description of the present disclosure, the meaning of “plurality” is at least two, for example, two, three, etc., unless specifically defined otherwise.

In the description of this specification, the description referring to the terms “one embodiment”, “some embodiments”, “an example”, “specific examples”, or “some examples” mean the specific feature, structure, material or characteristic described in conjunction with the embodiments or examples is included in at least one of the embodiments or examples of the present disclosure. In this specification, the schematic representation of the above terms does not necessarily refer to the same embodiment or example. Moreover, the specific feature, structure, material, or characteristic described may be combined in any suitable manner in any one or more embodiments or examples. In addition, without contradicting each other, different embodiments or examples and features in different embodiments or examples described in this specification may be integrated or combined by those skilled in the art.

Although the embodiments of the present disclosure have been shown and described above, it should be understood that the above-mentioned embodiments are exemplary and should not be construed as limitations to the present disclosure. Change, modification, replacement and variation may be made to the above-mentioned embodiments by those skilled in the art within the scope of the present disclosure.

What is claimed is:

1. An ultrasonic fingerprint identification assembly, comprising:
a substrate;
a receiving electrode on a side of the substrate;
a piezoelectric layer on a side of the receiving electrode away from the substrate;
a transmitting electrode on a surface of the piezoelectric layer away from the substrate; and
a metal electrode electrically connected to the transmitting electrode;
wherein an orthographic projection of the piezoelectric layer on the substrate fails within a combination of orthographic projections of the receiving electrode and the metal electrode on the substrate.

2. The ultrasonic fingerprint identification assembly according to claim 1, wherein,
a material for forming the metal electrode comprises at least one of copper, molybdenum, or titanium-aluminum-titanium,
a material for forming the transmitting electrode comprises silver, and
a material for forming the receiving electrode comprises iridium tin oxide.

3. The ultrasonic fingerprint identification assembly according to claim 1, wherein the metal electrode is disposed on a side of the receiving electrode away from the piezoelectric layer.

4. The ultrasonic fingerprint identification assembly according to claim 3, wherein the metal electrode is electrically connected to the transmitting electrode through a via hole.

5. The ultrasonic fingerprint identification assembly according to claim 3, further comprising:
a thin film transistor between the receiving electrode and the substrate, a drain of the thin film transistor being electrically connected to the receiving electrode.

6. The ultrasonic fingerprint identification assembly according to claim 5, further comprising a buffer layer between the substrate and the thin film transistor,
wherein the metal electrode is disposed between the substrate and the buffer layer, and the metal electrode is connected to the transmitting electrode through a via hole in the buffer layer.

7. The ultrasonic fingerprint identification assembly according to claim 5, wherein the metal electrode has an opening, and an orthographic projection of an active layer of the thin film transistor on the substrate at least partially overlaps with an orthographic projection of the opening on the substrate.

8. The ultrasonic fingerprint identification assembly according to claim 6, wherein the orthographic projection of the piezoelectric layer on the substrate falls within the orthographic projection of the metal electrode on the substrate.

9. The ultrasonic fingerprint identification assembly according to claim 5, wherein an organic film layer of the thin film transistor comprises a fit organic film layer and a second organic film layer stacked on each other, and the metal electrode patterned is disposed between the first organic film layer and the second organic film layer.

10. The ultrasonic fingerprint identification assembly according to claim 1, further comprising an insulating layer between the piezoelectric layer and the receiving electrode.

11. An ultrasonic fingerprint identification device, comprising the ultrasonic fingerprint identification assembly according to claim 1.

12. The ultrasonic fingerprint identification device according to claim 11, wherein,
a material for forming the metal electrode comprises at least one of copper, molybdenum, or titanium-aluminum-titanium,
a material for forming the transmitting electrode comprises silver, and
a material for forming the receiving electrode comprises indium tin oxide.

13. The ultrasonic fingerprint identification device according to claim 11, wherein the metal electrode is disposed on a side of the receiving electrode away from the piezoelectric layer.

14. The ultrasonic fingerprint identification device according to claim 13, wherein the metal electrode is electrically connected to the transmitting electrode through a via hole.

15. The ultrasonic fingerprint identification device according to claim 13, wherein the ultrasonic fingerprint identification assembly further comprises:
a thin film transistor between the receiving electrode and the substrate, a drain of the thin film transistor being electrically connected to the receiving electrode.

16. The ultrasonic fingerprint identification device according to claim 15, wherein the ultrasonic fingerprint identification assembly further comprises a buffer layer between the substrate and the thin film transistor,
wherein the metal electrode is disposed between the substrate and the buffer layer, and the metal electrode is connected to the transmitting electrode through a via hole in the buffer layer.

17. The ultrasonic fingerprint identification device according to claim 15, wherein the metal electrode has an opening, and an orthographic projection of an active layer of the thin film transistor on the substrate at least partially overlaps with an orthographic projection of the opening on the substrate.

18. The ultrasonic fingerprint identification device according to claim 16, wherein the orthographic projection of the piezoelectric layer on the substrate fails within the orthographic projection of the metal electrode on the substrate.

19. The ultrasonic fingerprint identification device according to claim 15, wherein an organic film layer of the thin film transistor comprises a first organic film layer and a second organic film layer stacked on each other, and the metal electrode patterned is disposed between the first organic film layer and the second organic film layer.

20. A display apparatus, comprising:
a display panel; and
the ultrasonic fingerprint identification assembly according to claim 1, the ultrasonic fingerprint identification assembly being disposed on a non-light-emitting surface of the display panel.
